(19) United States
(12) Patent Application Publication
(10) Pub. No.: US 2005/0242143 A1
(43) Pub. Date: Nov. 3, 2005

(54) Protective enclosure with a line-out device adapted for use with electronic componentry

(76) Inventor: Eric S. Hassett, Golden, CO (US)

Correspondence Address: SHERIDAN ROSS PC, 1560 BROADWAY, SUITE 1200, DENVER, CO, 80202, US

(21) Appl. No.: 11/173,256

(22) Filed: Jul. 1, 2005

Related U.S. Application Data
(63) Continuation-in-part of application No. 10/903,086, filed on Jul. 30, 2004.
Application No. 10/903,086 is a continuation-in-part of application No. 10/409,463, filed on Apr. 7, 2003, now Pat. No. 6,915,934.
Application No. 10/409,463 is a continuation-in-part of application No. 29/171,089, filed on Nov. 15, 2002, now Pat. No. D481865.
(60) Provisional application No. 60/438,916, filed on Jan. 8, 2003.

(51) Int. Cl. H05K 9/00; A45C 15/00

(52) U.S. Cl. 224/576; 224/930

(57) ABSTRACT

A protective enclosure capable of storing an electronic device while protecting it from damage emanating from impacts, impingements, dust and moisture is provided herein. More specifically, the present invention allows a user to use a portable electronic device without requiring the user to open the enclosure and expose the contents to inclement weather.

This application is a continuation-in-part of U.S. patent application Ser. No. 10/903,086, filed Jul. 30, 2004, which is a continuation-in-part of U.S. patent application Ser. No. 10/409,463, filed Apr. 7, 2003, which is a continuation-in-part of U.S. patent application Ser. No. 29/171,089, now Design Patent D481,865, filed Nov. 15, 2002 and which claims the benefit of U.S. Provisional Patent Application Ser. No. 60/438,916, filed Jan. 8, 2003, all pending applications and issued patents being incorporated by reference in their entirety herein.

### FIELD OF THE INVENTION

The present invention relates to apparatus that secure and protect electronic devices such as a compact disc players from impacts and water damage, and which allows a user to gain limited access to the enclosure without jeopardizing the water resistant integrity of the device. More specifically, in one embodiment of the present invention an enclosure is provided that is adapted to secure a portable compact disc (hereinafter “CD”) player and a plurality of CDs that includes an external connection port for a user interface, such as a headset listening device.

### BACKGROUND OF THE INVENTION

Storage cases and enclosures for transporting and protecting CD players, CDs, MP3 players, Personal Data Assistants (PDAs), mini-disc players, transistor radios, two-way radios, amplifiers, and cellular phones (hereinafter “electronic device”) are common. Traditionally, these enclosures are constructed from a resilient material such as nylon and in some embodiments include a clam-shell opening that is selectively secured with a zipper, a hook and loop fastener, or other type of securing device. Furthermore, some enclosures are capable of carrying both an electronic device and items used within the device, such as a CD player and a plurality of CDs. Depending on the material of construction, many traditional enclosures provide limited protection from impacts, scratches, and fluids. Unfortunately, in order to provide such protection from the outside elements, the enclosure must be sealed, thereby preventing or restricting access to the electronic device.

Portable music listening devices allow people to enjoy music during outdoor activities. In order to enjoy music without disturbing others, a user must generally use a headset or ear piece(s). However, to gain access to connection ports on the electronic device, the enclosure must be opened thus making the contents more susceptible to damage, especially in inclement weather. Generally, a user will remove the electronic device and hold or clip it to a garment while participating in an activity. Alternatively, a user may try to exploit some of the protective aspects of a particular enclosure while listening to music. For example, a zipper on an enclosure may be opened partially to gain limited access to the electronic device, but this method may allow contents to fall out and be lost or damaged, especially during rigorous physical activity such as skiing, snow boarding, etc. Furthermore, any opening in the enclosure provides a pathway where fluids may come in contact with the electronic device and cause damage or destroy the sensitive electronic components.

Thus, there is a long felt need in the field of electronic device storage to provide a cost effective enclosure that is capable of protecting the internal contents from impact and external elements, while providing selective access to the electronic componentry via headphones or other similar devices such that the electronic device can be safely and effectively enjoyed without compromising the integrity of the enclosure.

### SUMMARY OF THE INVENTION

It is thus one aspect of the present invention to provide a protective enclosure that is capable of storing an electronic device, such as a portable CD player, cassette player, MP3 player, radio, notebook computer or any other type of electronic device that is capable of transmitting information via a hard-line connected to headphones or other type of input or output device.

It is another aspect of the present invention to provide a “line-out” device, wherein a user can gain access to the electronic device without substantially breaching the integrity of the enclosure. For example, in one embodiment of the present invention an aperture is integrated into the enclosure along with a protective sheath interconnected to the enclosure in the same general location. This aperture provides access to the internal portion of the enclosure while the enclosure is substantially sealed to prevent water damage, or exposure to other external elements such as sand or dirt. In one embodiment, an auxiliary hard-line may be employed to span the distance between the aperture and the electronic device's listening port. The extension may also be adapted with an end housing that has a greater diameter than the transmission line. When inserted into the aperture and at least partially covered with the sheath, the thicker end creates a seal that substantially provides a barrier to fluid. Therefore, when the enclosure is closed, maximum protection against impact and water damage is provided, while the listening port is effectively transferred to the outside of the enclosure to provide an access port for the user's headset, other listening device or other control mechanism. This feature is especially useful for snowboarders, skiers, runners, backpackers, boaters, skaters, and other outdoor sports enthusiasts who may encounter inclement weather.

It is yet another aspect of the present invention to provide a water and dust resistant enclosure for electronic devices, wherein the electronic device may be enjoyed without exposing the sensitive electronics to moisture, sand and other elements, such that electronic device may be enjoyed during outdoor activities, such as snow boarding. As mentioned above, the auxiliary extension line that fits snugly into the aperture integrated into the enclosure provides some protection, but increased protection is easily achievable. In one embodiment, a gasket, which interfaces with the sheath and the enclosure, provides a more watertight seal. Alternatively, a means may be provided wherein an end of the auxiliary line is selectively interconnected to the enclosure to provide a more rigid, watertight, interface. In order to prevent fluids from entering through zippers, which may be integrated into the enclosure, other water proofing devices may be required. For example, in one embodiment, an additional flap of material is provided that is capable of folding over a closed zipper and is selectively interconnected to the enclosure, effectively concealing the zipper and providing additional protection from zipper opening and fluid penetration. Alternatively, in another embodiment a selective interconnection that is inherently water proof is employed that is similar to those used on ZIP-LOC™ bags. Finally, the enclosure may be substantially constructed of water repellant or water proof materials to prevent fluid penetration through the “skin” of the enclosure.

It is another aspect of the present invention to provide an electronic device enclosure that is easy to transport such that it does not substantially interfere with the user's activities. For example, in one embodiment of the present invention, a strap is provided such that the enclosure may be selectively positioned over the user's shoulder or around their waist. Alternatively, belt loops, clips, or other attachment devices may be provided for attachment to a backpack, coat pocket, etc. Alternatively, the enclosure may be a backpack, brief case, attache case, etc. with an integrated in-line device as described herein. One skilled in the art will appreciate any number of attachment means may be utilized to allow a user greater freedom and mobility while using the protective enclosure and associated electronic device.

It is still yet another aspect of the present invention to provide access to an electronic device while it is enclosed and protected. The enclosure with the line-out feature, as described above, more effectively protects the enclosed electronic device. However, in order to effectively utilize various functions of the electronic device such as volume, song selection, etc., it may be necessary for a user to breach the main opening, thereby exposing the delicate electronic componentry to the elements. For example, a user may wish to change the track of a CD, or make a two-way call while on a ski slope. By opening the enclosure to access the enclosed electronic device, the user increases the chance that moisture will come in contact with the electronic device. As mentioned above, one embodiment of the present invention is constructed from resilient materials. If the user is aware of the general area of function-initiating buttons on a particular electronic device, he or she can simply squeeze or press down on the resilient material to initiate a song change, for example. Although generally effective, the lack of visibility through the often opaque enclosure may be a problem. Also, the task may be more difficult if the user is wearing gloves wherein his or her sensation of touch is limited. Therefore, it is another embodiment of the present invention to provide a transparent viewing area in the enclosure to provide visibility to one or more buttons of the electronic device to allow a user to identify the desired buttons or function.

In another embodiment of the present invention, a flap is provided that is selectively interconnected to the enclosure body that allows limited access to the buttons, knobs, etc. of the electronic device. A flap of water resistant material may be fastened to the enclosure with stitching, zippers, or hook and loop fasteners. As appreciated by one skilled in the art, any number of methods including those described above may be employed to the periphery of the enclosure to allow selective interconnection and limited access to the enclosure's contents. Furthermore, a section of resilient material may be integrated into an enclosure constructed from a rigid material, wherein a user could access the buttons of the electronic devices by pressing the less rigid resilient material. Alternatively, one or more rigid or flexible buttons may be provided that may be accessed from the exterior of the enclosure, but which provide operable communication to the various modes of selection provided on the electronic device.

It is a further aspect of the present invention that pockets are provided to store items in the water resistant environment. In one embodiment of the present invention, pockets or sleeves are provided that are capable of receiving a plurality of CDs. Alternatively, other pockets on the inside and outside of the enclosure may be employed to protect items such as keys, money, ski lift passes, driver's licenses, credit cards, etc., from damage or loss.

It is still yet another aspect of the present invention to provide a protective enclosure that is constructed from known materials and thus inexpensive to manufacture. For example, one resilient embodiment of the present invention is constructed with one or a combination of water resistant materials such as nylon, Gore-TEX®, polypropylene, polyethylene, rubber, treated leather, elastic, and/or plastic. One skilled in the art will appreciate that any resilient material with water resistant properties, may be employed without departing from the scope of the invention. In addition, padding such as foam rubber, is preferably added in various predetermined locations to increase the impact resistance of the enclosure. Alternatively, another embodiment of the present invention is constructed from rigid materials that further increase the impact protection aspect of the present invention. Finally, the enclosure of the present invention may be made in a plurality of shapes, sizes, materials of various colors, and may embody advertisements, logos, or endorsements.

It is another aspect of the present invention to provide a line-out device that has a female end that is operably interconnected to a housing. More specifically, one embodiment of the present invention includes a line-out device housing that encapsulates the female end of the line-out device, thus preventing fluids from entering the protective enclosure. Preferably, this embodiment of the present invention also includes a flange substantially around the housing of the line-out device for interconnection to the protective enclosure. The housing of the line-out device may be made from rigid materials or semi-rigid materials, but accommodate some compliance to provide an interference fit between the female end of the line-out device and the housing. One embodiment of the housing is made of molded rubber wherein the female end of the line-out device is integrated into the housing during fabrication. This manufacturing method provides a tight seal between the female end or the line-out device and the housing to prevent liquids from entering into the protective enclosure. The flange of the housing may include a plurality of apertures to facilitate interconnection to the protective enclosure with stitching. Alternatively, the flange may provide a location for the application of adhesives, welds, etc.

One embodiment of the present invention includes a female end that is oriented at an angle from the housing flange to facilitate interconnection of the male end of a listening device, such as speakers or earphones. More specifically, the male ends of the listening device, which are similar to those shown and described herein, often protrude from a housing that provides a gripping location. In order to prevent structural interferences and to facilitate interconnection of the male end of the listening device to the female end of the line-out device, it may be necessary to angle the female end from the plane of the portable enclosure. This embodiment of the present invention sets such an angle by selectively molding the female end into the housing during construction.

It is still yet another aspect of the present invention to provide a line-out device that includes a plurality of female ends. More specifically, one embodiment of the present invention includes at least two female ends that originate from a common wire that extends to the male end, thus providing locations for the interconnection of a plurality of listening devices and thus allowing two different users to utilize the CD player on other electronic componentry. This embodiment of the present invention may be constructed by integrally molding female ends into a housing as described above.

In operation, the line-out device with a plurality of female ends is envisioned to be used with a protective enclosure for a DVD player. More specifically, one embodiment of the present invention is a DVD player case that includes the line-out device with at least two female ends, wherein a plurality of users may selectively access the DVD player. This embodiment of the present invention is ideally employed in a situation wherein a portable DVD player is used on an airplane or a motor vehicle. The users, generally sitting in the rear compartment of an automobile or next to each other in the aircraft, may selectively access the DVD player with headsets such that other passengers are undisturbed by the viewing of the DVD. Alternatively, one skilled in the art will appreciate that this embodiment of the present invention may be integrated into a storage case a for music listening device such that the device may be enjoyed by a plurality of users wherein the music will not disturb other individuals in the general vicinity.

Thus, it is one aspect of the present invention to provide an enclosure adapted for holding and protecting an electronic device, comprising:
a front portion selectively interconnected to a rear portion, wherein said enclosure may be selectively opened and closed;
an aperture in said enclosure; and
a housing interconnected to the enclosure that is adapted to receive and secure an auxiliary cord, thereby substantially preventing liquids from entering said enclosure through said aperture.

The Summary of the Invention is neither intended nor should it be construed as being representative of the full extent and scope of the present invention. The present invention is set forth in various levels of detail in the Summary of the Invention as well as in the attached drawings and the Detailed Description of the Invention and no limitation as to the scope of the present invention is intended by either the inclusion or non-inclusion of elements, components, etc. in this Summary of the Invention.

### BRIEF DESCRIPTION OF THE DRAWINGS

The accompanying drawings, which are incorporated in and constitute a part of the specification, illustrate embodiments of the invention and together with the general description of the invention given above and the detailed description of the drawings given below, serve to explain the principles of these embodiments.

FIG. 1 is a rear perspective view of one embodiment of the present invention;

FIG. 2 is a front elevation view of the invention shown in FIG. 1;

FIG. 3 is a partial auxiliary section view of the invention shown in FIG. 1;

FIG. 3a is a partial auxiliary section view of another embodiment of the present invention shown in FIG. 3;

FIG. 3b is a partial auxiliary section view of another embodiment of the present invention shown in FIG. 3;

FIG. 3c is a partial auxiliary section view of another embodiment of the present invention shown in FIG. 3;

FIG. 4 is a rear elevation view of the invention shown in FIG. 1;

FIG. 5 is a right elevation view of the invention shown in FIG. 1;

FIG. 6 is a left elevation view of the invention shown in FIG. 1;

FIG. 7 is a top plan view of the invention shown in FIG. 1;

FIG. 8 is a bottom plan view of the invention shown in FIG. 1;

FIG. 9 is a perspective view of another embodiment of the present invention showing a line-out device that includes a female end that is integrated into a housing;

FIG. 10 is a perspective view of the embodiment of the present invention shown in FIG. 9 in a closed position;

FIG. 11 is a left elevation view of the embodiment of the present invention shown in FIG. 10;

FIG. 12 is a front elevation view of the embodiment of the present invention shown in FIG. 10;

FIG. 13 is a top plan view of the embodiment of the present invention shown in FIG. 10;

FIG. 14 is a right elevation view of the embodiment of the present invention shown in FIG. 10;

FIG. 15 is a rear elevation view of the embodiment of the present invention shown in FIG. 10;

FIG. 16 is a bottom plan view of the embodiment of the present invention shown in FIG. 10;

FIG. 17 is a partial cross-section view of the embodiment of the present invention shown in FIG. 12;

FIG. 18 is a front elevation view of an alternative embodiment of a line-out device; and

FIG. 19 is a front elevation view of the alternative embodiment of the line-out device shown in FIG. 18.

To assist in the understanding of the present invention, the following list of components and associated numbering found in the drawings is provided herein:
#Component
10 Protective enclosure
14 Electronic device storage compartment
15 Front portion of enclosure
16 Rear portion of enclosure
17 Transparent material
18 Selective interconnection means
22 Sheath
24 Aperture
26 Line-out device
28 Male end of line-out device
30 Female end of line-out device
32 Flexible seal
34 Threaded interface
35 Listening device plug
36 Storage pocket
40 Panel
42 Securing location
44 Strap
46 Housing
48 Flange

It should be understood that the drawings are not necessarily to scale. In certain instances, details which are not necessary for an understanding of the invention or which render other details difficult to perceive may have been omitted. It should be understood, of course, that the invention is not necessarily limited to the particular embodiments illustrated herein.

### DETAILED DESCRIPTION

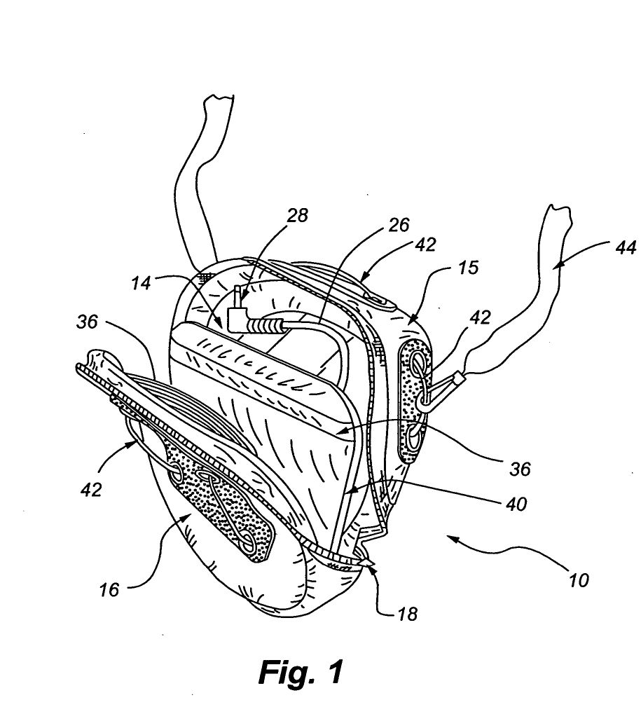

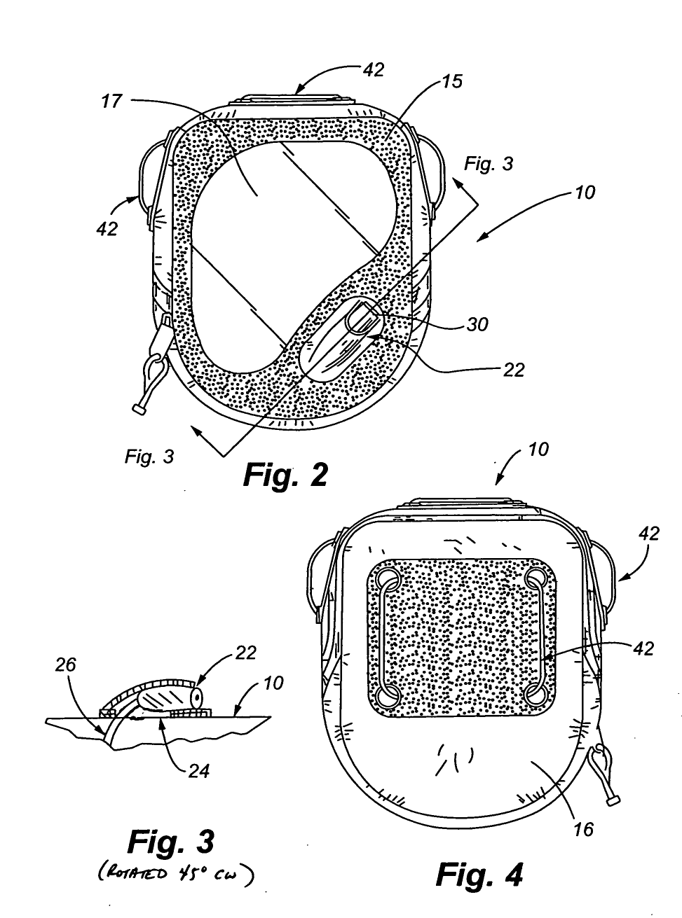

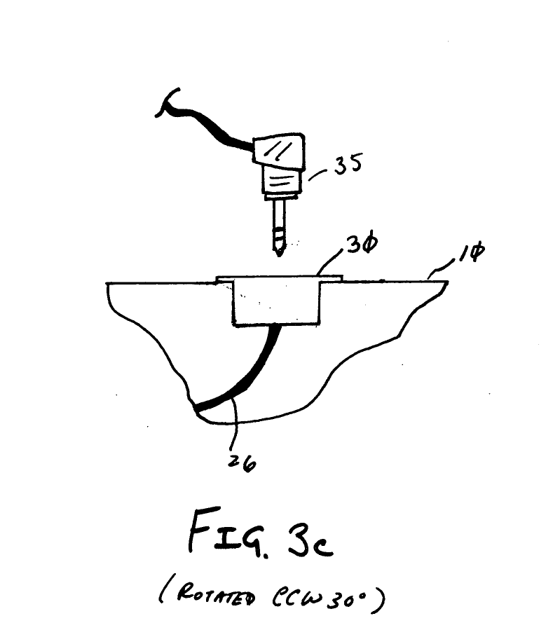

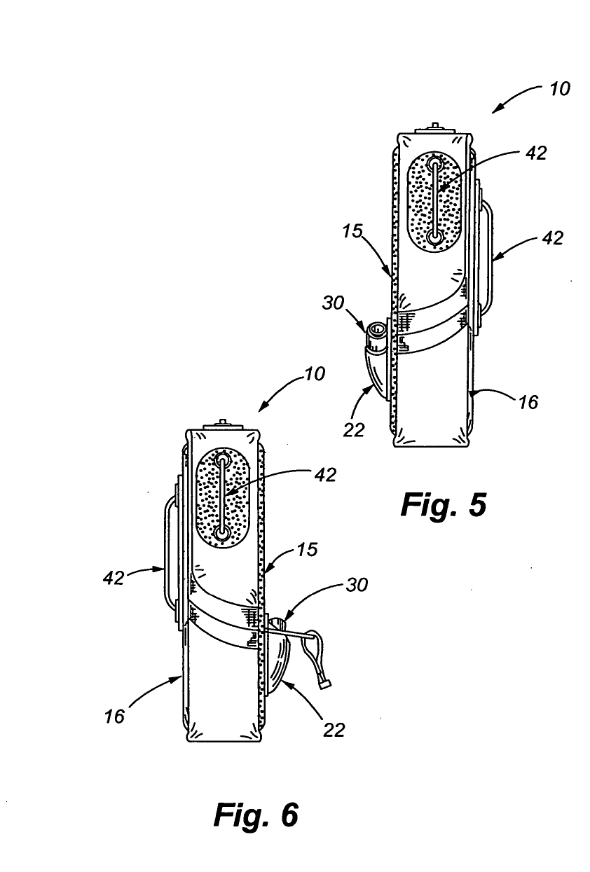

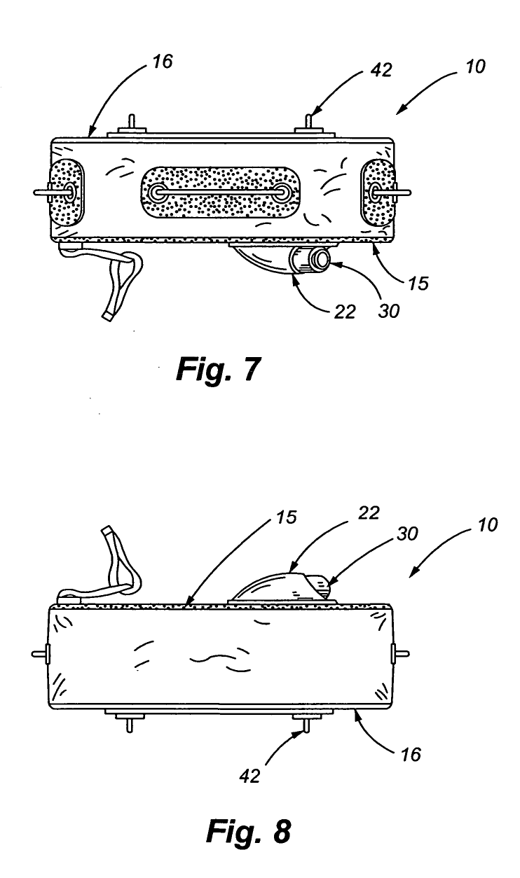

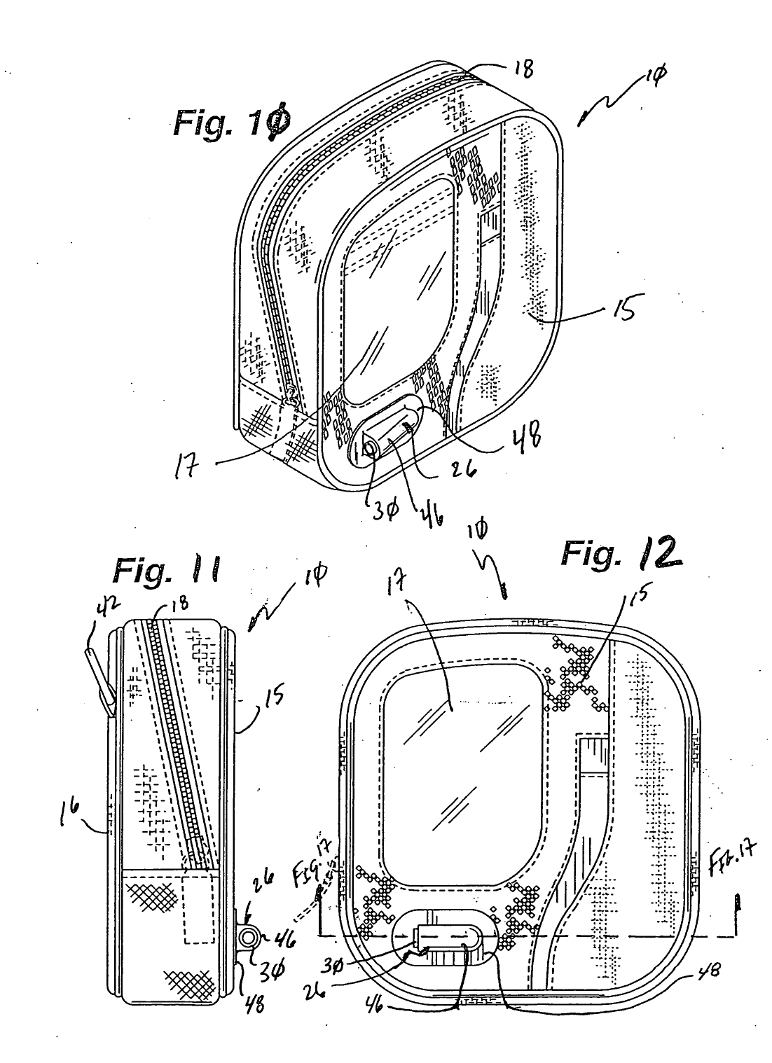

FIGS. 1-19 depict an enclosure for securing an electronic device that protects the electronic device from impact, water and dust damage, and which includes a line-out device that allows interconnection of a listening device without opening the enclosure. More specifically, a CD player enclosure with a plurality of CD pockets is shown that secures the contents therein with a zipper. The line-out device provides selective access for a user's headsets, earpieces, or speakers, while maintaining closure of the main opening, to prevent infiltration of snow, rain, dust and other foreign objects.

Referring now to FIGS. 1-8, one embodiment of the present invention is shown herein. Generally, the electronic device protective enclosure 10 comprises a pouch that defines a compartment 14 that secures the electronic device. A front portion 15 and a rear portion 16 of the pouch are generally closed by a selectively securing means 18, for example a zipper, a loop and hook type fasteners, etc. In one embodiment, the enclosure 10 is constructed from a compliant, water resistant material such as nylon. One skilled in the art will appreciate that other compliant or non-complaint water resistant materials may be used in the construction of the entirety or portions of the enclosure, including, but not limited to Gore-TEX®, polyethylene, poly propylene treated leather, plastic, neoprene, and other materials well known in the art. Preferably, a transparent or semi-transparent material 17 is integrated into the front portion 15 of the enclosure 10 that allows an individual to see the electronic device or other items carried in the enclosure 10.

Referring now to FIGS. 1-3, a fluid-resistant access device of one embodiment of the present invention is shown in use with the protective enclosure 10. In order to substantially impede liquids from penetrating the inside of the enclosure 10, a protective sheath 22 is utilized. Preferably, the sheath 22 is interconnected onto the front portion 15 or rear portion 16 of the enclosure 10. The sheath 22 is interconnected to the enclosure 10 preferably by stitching, but one skilled in the art will appreciate many other methods of interconnection are possible that will impede fluid transfer from the outside, such as adhesives, rivets, etc. The sheath 22 provides a substantially waterproof engagement to an aperture 24, which is integrated into a portion of the enclosure 10, and which allows an auxiliary device such as a headphone cable to penetrate therethrough.

More specifically, a “line-out” device 26, is provided, that is adapted to pass through the aperture 24 and fit snugly in the sheath 22 as shown. In one embodiment of the present invention, the line-out device 26 is a conductive electrical cord, with a male end 28 and a female end 34, which is intended to be an extension cord that is accessed by the user's headset cord, for example. In one embodiment the female end 30, which is of a larger diameter than the line-out device's cord, fits snugly in the sheath and effectively provides a fluid resistant seal. It is important to note that the female end 30 does not necessarily have to be completely surrounded by the sheath 22. A portion of the female end 30 may rest against the enclosure 10 surface adjacent to the aperture 24 which, with the aid of the sheath 22, provides a fluid resistant barrier.

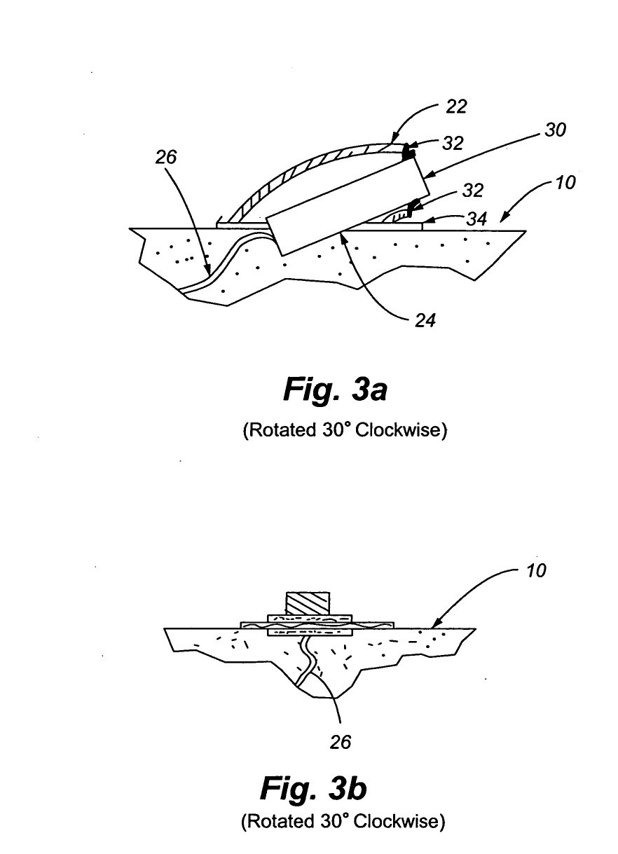

Referring now to FIG. 3a, another embodiment of the sheath 22 is provided herein. As described above, the sheath 22 acts as a cover for the aperture 24 and as a seal when it is selectively interconnected to an end of a line-out device 26. In order to provide greater protection from the infiltration of fluid into a protective enclosure 10, in an alternative embodiment of the present invention, a flexible seal 32 is provided. More specifically, the seal 32 is interconnected to the sheath 22 and is adapted to receive a portion of the line-out device 26, thereby completely surrounding the female portion 30 thereof. The seal 32 may be constructed from rubber, neoprene, or any other substantially resilient material commonly known in the art that is water resistant. Alternatively, compression fit hardware and associated resilient bushings and/or gaskets may be utilized to provide the same function of a watertight seal. In another embodiment of the present invention a secondary seal 34 is provided that is interconnected to an outside surface of the enclosure 10, to provide even greater protection from the infiltration of foreign objects such as dust or moisture. Finally, in yet another embodiment of the present invention, the sheath 22 may be constructed entirely from a resilient and/or fluid resistant material such that when a portion of the line-out device 26 is interconnected to it, the resilient nature of the material will provide a tighter seal.

Referring now to FIG. 3b, another embodiment of the water resistant port is described herein. More specifically, in this embodiment a substantially water-tight access port is provided that is interconnected to a protective enclosure 10 and omits the need for a sheath, as shown. In this embodiment the line-out device 26 is securely interconnected to the enclosure 10. A threaded interface 34 provides a location for selective interconnection of a headset or other listening device. An interface 34 as described herein has the added benefit of insuring the user's output device does not inadvertently disconnect at undesired times.

Referring now to FIG. 3c, yet another embodiment of the water resistant port is shown. More specifically, in this embodiment, the female end of the line out device 30 is integrated directly into the protective enclosure 10, which in one embodiment is a backpack or attache. The line of the line-out device 26 is then interconnected to the electronic device. One skilled in the art, however, will appreciate that the female end of the line-out device 30 may be wirelessly interconnected or otherwise in communication with the electronic device. In operation, the user interconnects a listening device an earphone plug 35 into the female end of the line-out device 30 to thus provide audio and/or visual information to earphones, speakers, DVD players or a similar electronic device.

One skilled in the art will appreciate that a male connector, or any electronic connector for transmitting information to a listening device, may be integrated onto the enclosure 10 without departing from the scope of the invention.

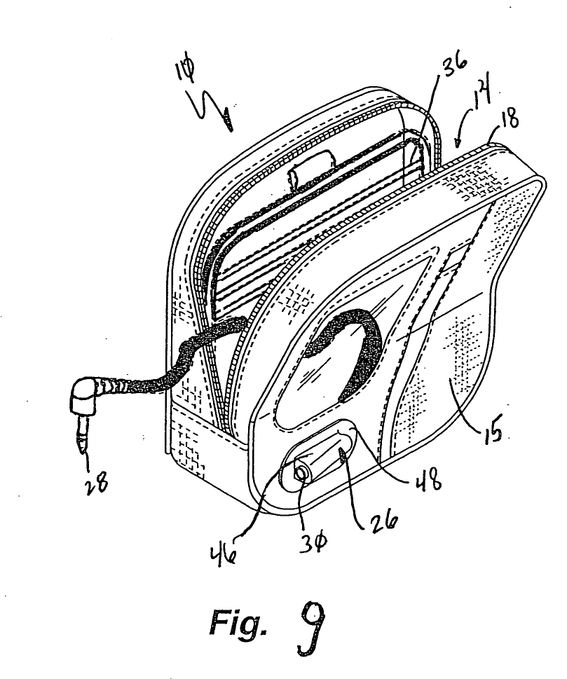

Referring now to FIGS. 9-19, another embodiment of the present invention that utilizes a line-out device 26 that includes a female end 30 integrated into a housing 46 is shown herein. More specifically, a protective enclosure 10 as previously described is shown, however the line-out device in this embodiment of the present invention includes a female end 30 that is integrally positioned into the housing 46 of the line-out device 26, and which may include a flange 48 that is adapted to be interconnected to the protective enclosure.

Referring specifically now to FIG. 17, one embodiment of the line-out device 26 is shown herein in a cross-sectioned front elevation view. More specifically, this embodiment of the line-out device 26 includes a female end 30 that is adapted to receive a male end of a listening device and which is integrated directly into the housing 46. In addition, this embodiment of the present invention includes a flange 48 that is adapted for interconnection to the protective enclosure 10. One skilled the in art will appreciate that the depiction of the female end 34 of the line-out device 10 is a generalization and that any type of interconnecting device generally used with electronic devices may be used such as coaxial cables for example, without departing from the scope of the invention. The female end is interconnected to a wire that leads to the male end 28 that is adapted for interconnection to the entertainment device.

The housing 46 of one embodiment of the invention is constructed of molded rubber, wherein the female end 30 of the line-out device is situated into a mold prior to the introduction of the rubber into the mold. After the molding operation is complete, a single piece structure that includes the generally metallic female end 30 and the molded rubber housing 46, which may include a flange 48, will be provided. This structure is inherently sealed such that fluids may not easily penetrate into the inside of the protective enclosure 10. In addition, as shown herein, the female end 30 may be positioned at an angle (θ), thus facilitating interconnection of a male end of a listening device, such as headphones or a speaker. After molding, the male end 28 of the line-out device is threaded through the aperture 24 of the protective enclosure 10 and the flange 48 fastened thereto. One skilled in the art will appreciate there are many fastening means that may be employed without departing from the scope of the invention. For example, the flange 48 and housing 46 may be interconnected to the protective enclosure 10 with stitching, heat welding, adhesives, etc.

It should be understood that the concept of integrally molding the female end 30 of the line-out device 26 may be employed on a larger scale. For example, a front portion 15 or rear portion 16 of the protective enclosure that supports the female end 30 of the line-out device 10 may be constructed of a compliant material such as rubber, wherein the housing may be integrally molded. This portion would then be interconnected to the remaining portion of the protective enclosure 10 to create the storage case as shown herein. This option would save time and money wherein the flange 48 of the line-out device 26 would not require interconnection to the protective enclosure 10.

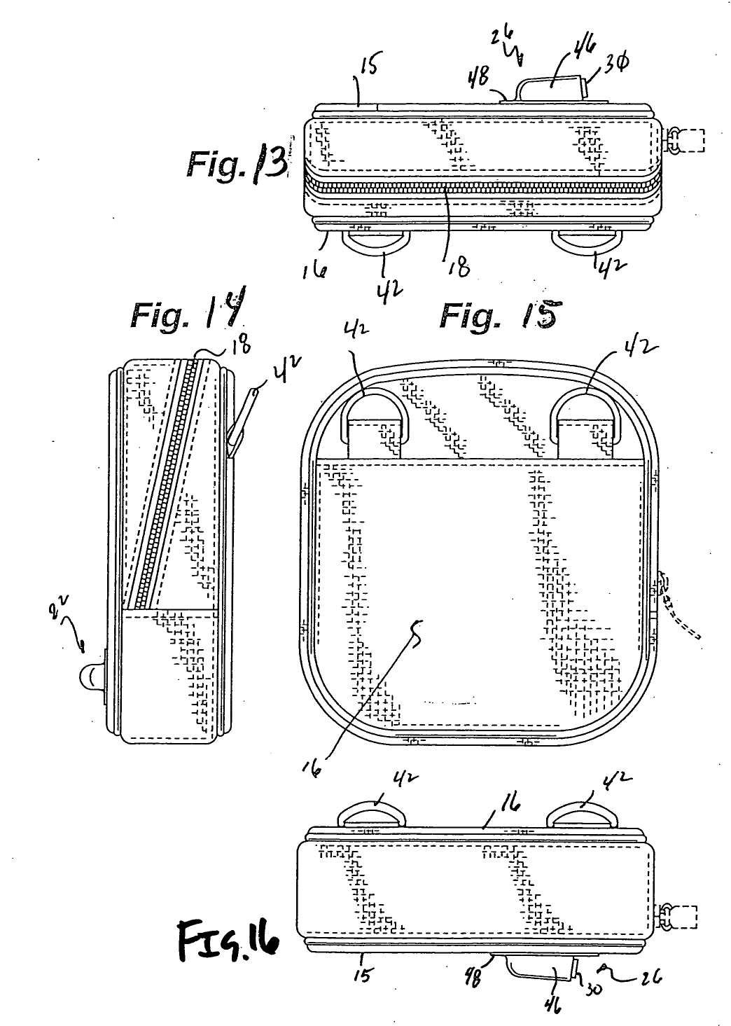

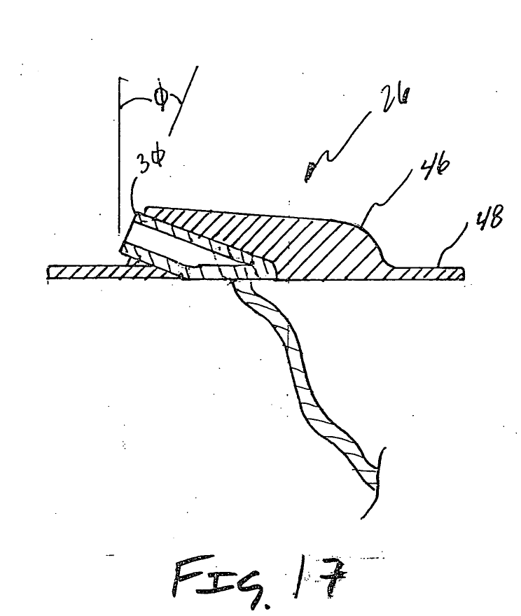

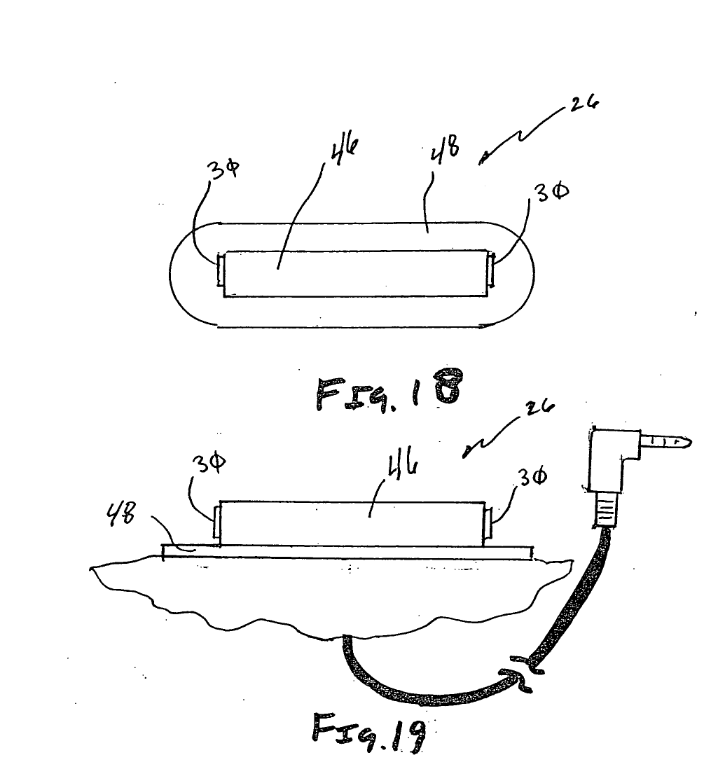

Referring now to FIGS. 18 and 19, another embodiment of the line-out device 26 is shown herein that includes a plurality of female ends 30. More specifically, one embodiment of the present invention includes at least two female ends 30 that are interconnected to the male end 28 of the line-out device. As shown herein, one embodiment of the present invention is constructed by integrally molding female ends 30 with a housing 46 that interconnects to the protective enclosure 10. The female ends 30 join a single wire that leads to the male end 28 for interconnection to an entertainment device. Although shown herein generally parallel to the flange 48, the female ends 34 of this embodiment of the present invention may be positioned at an angle as described above to facilitate the interconnection of a plurality of listening devices. This embodiment of the present invention allows for listening and enjoyment of music or a DVD, for example, by a plurality of individuals who want to listen to the same music.

Referring again to FIGS. 1-19, additional aspects of the present invention are shown and described herein. In one embodiment of the present invention, additional storage pockets 36 are provided, for holding CDs, for example. The storage pockets 36 may be interconnected to the inner surface of the rear portion 16 of the enclosure 10, or alternatively an additional panel 40 may be provided that is operably interconnected to an inner surface of the enclosure 10. Preferably, the panel 40 is constructed of padded material to provide greater protection to the electronic device carried within. In addition, the enclosure 10 may be provided with securing locations 42 wherein a strap 44 may be attached or that are adapted to receive a belt. Finally, as appreciated by one skilled in the art, the enclosure 10 may be constructed of materials of various colors or a combination thereof and may be adapted to display advertisements, company logos, etc.

In order to protect the electronic device, a user places the device into the storage compartment 14 of the protective enclosure 10. Other items such as, but not limited to, music media, keys, credit cards, and currency may be stored in the additional pockets 36. For example, in one embodiment of the present invention, the storage compartment 14 is capable of accepting a portable CD player, while the pockets 36 are capable of receiving CDs. Next, the line-out device 26, which is adapted to be used with the electronic device, is selectively interconnected to the electronic device. The other end of the line-out device 26, is then engaged with the aperture 24 of the enclosure and operably interconnected to the sheath with a snug interference fit to provide a substantially watertight seal. Finally, the user selectively interconnects the output device, i.e., headphones, to the portion of the line-out device accessible from the exterior of the enclosure 10, and selectively interconnects the front portion 15 and the rear portion 16 to ensure substantially complete protection against impacts and penetration from fluids, dust, etc. While various embodiments of the present invention have been described in detail, it is apparent that modifications and alterations of those embodiments will occur to those skilled in the art. However, it is to be expressly understood that such modifications and alterations are within the scope and spirit of the present invention, as set forth in the following claims.

1. An enclosure adapted for holding and protecting an electronic device, comprising:
a front portion selectively interconnected to a rear portion, wherein said enclosure may be selectively opened and closed;
an aperture in said enclosure; and
a housing interconnected to the enclosure proximate to said aperture that is adapted to receive and secure a conductive auxiliary cord, thereby substantially preventing liquids from entering said enclosure through said aperture, wherein said auxiliary cord is adapted for operable interconnection to at least one of an electric device and a listening device.

2. The enclosure of claim 1, wherein said enclosure comprises at least one of a backpack, a compact disc carrying case, an mp3 player case, and a briefcase.

3. The enclosure of claim 1, further comprising an electronic device storage area positioned between said front portion and said rear portion to secure the electronic device within the enclosure.

4. The enclosure of claim 1, wherein the auxiliary cord further comprises a first end with a male connector interconnected thereto and a second end with a female connector interconnected thereto.

5. The enclosure of claim 1, wherein said housing includes a flange that is adapted for interconnection to the enclosure.

6. The enclosure of claim 1, wherein said front portion and said rear portion are selectively interconnected with a zipper.

7. The enclosure of claim 4, wherein said female connector is positioned at an angle relative to the enclosure.

8. The enclosure of claim 4, wherein said female connector is integrally interconnected to said housing.

9. The enclosure of claim 5, wherein at least one of said housing and said flange are comprised of a rubber material.

10. The enclosure of claim 5, wherein said flange is stitched to said enclosure.

11. The enclosure of claim 5, wherein said housing and said flange are comprised of a resilient material which forms a compression fit with the conductive auxiliary cord.

12. An enclosure adapted for holding and protecting an electronic device, comprising:
a front portion operably interconnected to a rear portion, wherein said enclosure may be selectively opened and closed;
an aperture in said enclosure which is adapted for allowing penetration of said enclosure by a conductive auxiliary cord; and
a sheath interconnected to said enclosure, proximate to said aperture, said sheath adapted to receive and sealingly engage a conductive auxiliary cord.

13. The enclosure of claim 12, wherein said front and rear portions are selectively interconnected by at least one of a zipper, a snap, a button and a hook-and-loop fastening material.

14. The enclosure of claim 12 further comprising at least one of a handle, a strap or a belt which is operably interconnected to said enclosure.

15. The enclosure of claim 12, wherein at least one of said front portion and said rear portion comprises at least one section of transparent material, wherein at least a portion of said electronic device can be viewed.

16. The enclosure of claim 12, wherein said storage area is adapted to receive at least one of a CD player, a MP3 player, a tape player, a mini-CD player, a cellular phone, a two-way radio, a computer and a radio receiver.

17. A weather resistant system for protecting a portable electronic device, comprising:
a water resistant enclosure adapted to secure the portable electronic device;
a housing operably interconnected to said enclosure, said housing further comprising an electrical connector which is adapted for electrical communication with the portable electronic device; and
wherein said electrical connector is adapted to interface with at least one of a speaker, a headset, a wireless antennae, and a video monitor, and wherein substantially ensuring the portable electronic device is protected from the elements.

18. The system of claim 17, wherein said enclosure comprises a backpack, an attache, a duffel bag, a camera case, an mp3 player case, a compact disc player case, a radio player case and a tape cassette player case.

19. The system of claim 17, further comprising a cord interconnected to said electrical connector and selectively interconnected to the portable electronic device.

20. The system of claim 17, wherein said electrical connector is at least partially comprised of at least one of a silicon, a rubber, a plastic, a leather material, a nylon, a polypropylene and a neoprene, thereby providing a generally resilient interconnection to said enclosure.

21. A flexible, substantially water resistant portable enclosure adapted to hold an electronic device, comprising:
an enclosure sized to receive the electronic device;
an opening means interconnected to said enclosure to allow the selective opening or closing of the portable enclosure;
a substantially water resistant housing means operably interconnected to said portable enclosure, said housing means adapted to receive an electrical conductive cord which is adapted for operable communication with the electronic device.

22. The portable enclosure of claim 21, wherein said opening means comprises at least one of a zipper, a flap and a hook and loop material.

23. The portable enclosure of claim 21, wherein said housing means comprises a sheath with a material comprised of at least one of a rubber, a plastic, a leather and a nylon material.

24. The portable enclosure of claim 21, wherein housing means further comprises a female electrical connection positioned therein which is adapted to receive conductive apparatus adapted for interconnection to an electronic disc.
